(19) United States
(12) Patent Application Publication
(10) Pub. No.: US 2023/0023178 A1
(43) Pub. Date: Jan. 26, 2023

(54) DISPLAY PANEL AND MOBILE TERMINAL

(71) Applicant: WUHAN CHINA STAR OPTOELECTRONICS SEMICONDUCTOR DISPLAY TECHNOLOGY CO., LTD., Wuhan, Hubei (CN)

(72) Inventor: Fuqiang YANG, Wuhan, Hubei (CN)

(21) Appl. No.: 17/438,278

(22) PCT Filed: Aug. 4, 2021
(86) PCT No.: PCT/CN2021/110472

§ 371 Date: Sep. 10, 2021

(30) Foreign Application Priority Data
Jul. 22, 2021 (CN) 202110832723.8

(51) Int. Cl. H01L 51/50; H01L 27/32; H04M 1/02

(52) U.S. Cl. CPC H01L 51/5072; H01L 27/3206; H01L 27/3246; H01L 51/5056; H04M 1/0266

(57) ABSTRACT

A display panel and a mobile terminal are disclosed. A light-emitting device layer of the display panel includes a plurality of first light-emitting units, a plurality of first compensation layers disposed corresponding to the first light-emitting units. The first compensation layers are located on at least one side of the first light-emitting units. A hole transport rate of the first compensation layers is greater than a hole transport rate of a hole transport layer, and/or an electron transport rate of the first compensation layers is greater than an electron transport rate of an electron transport layer.

### FIELD OF INVENTION

The present disclosure relates to the field of display technology, and more particularly, to a display and a mobile terminal.

### BACKGROUND OF INVENTION

In panel display technology, organic light-emitting diode (OLED) display has many advantages, such as thinness, self-illumination, high response speed, wide viewing angles, wide color gamut, high brightness, and low power consumption, and gradually becomes the third generation display technology following liquid crystal displays.

In the current structure of OLED displays, a hole common layer and an electron common layer are shared in adjacent sub-pixels. Therefore, when a voltage is supplied to one sub-pixel, holes generated by an anode or electrons generated by a cathode are transferred to an adjacent sub-pixel through the corresponding common layer, such that a starting voltage of the sub pixel is inaccurate, resulting in the technical problem of color shift occurring in OLED display device at low gray level.

Therefore, a display panel that solves the above technical problem is urgently required.

### SUMMARY OF INVENTION

### Technical Problem

A display panel and a mobile terminal are disclosed to solve the technical problem of color shift occurring in the existing OLED display panel at low gray level.

### Technical Solutions

A display panel is disclosed in the present disclosure, which includes a first electrode, a light-emitting device layer, and a second electrode stacked in order;
the light-emitting device layer includes a plurality of first light-emitting units emitting first color light, a plurality of first compensation layers disposed corresponding to the first light-emitting units, and a hole transport layer and an electron transport layer located on two sides of the first light-emitting units;
the first compensation layers are located between the first electrode and the first light-emitting units, and a hole transport rate of the first compensation layers is greater than a hole transport rate of the hole transport layer; and/or,
the first compensation layers are located between the second electrode and the first light-emitting units, and an electron transport rate of the first compensation layers is greater than an electron transport rate of the electron transport layer.

In the display panel of the present disclosure, the first compensation layers are located between the first electrode and the first light-emitting units;

the first compensation layers include a hole-type dopant having an electron withdrawing group.

In the display panel of the present disclosure, a concentration of the hole-type dopant ranges from 1% to 6%, and the hole-type dopant includes at least one of HAT-CN, F4-TCNQ, SbCI5 or FeCl3.

In the display panel of the present disclosure, the display panel includes a pixel definition layer, the pixel definition layer includes a plurality of pixel openings, and the first light-emitting units are located in the pixel opening;

The first electrode includes a first portion corresponding to the pixel opening, and a projection of the first portion projected on the second electrode is located in a projection of the first compensation layers projected on the second electrode.

In the display panel of the present disclosure, the first compensation layers are located between the second electrode and the first light-emitting units;

The first compensation layers include an electron-type dopant having an electron donating group.

In the display panel of the present disclosure, a concentration of the electron-type dopant ranges from 1% to 6%, and the electron-type dopant includes an alkali metal or an alkali metal salt.

In the display panel of the present disclosure, a projection of the first light-emitting units projected on the second electrode is located in a projection of the first compensation layers projected on the second electrode.

In the display panel of the present disclosure, the light-emitting device layer further includes a plurality of second light-emitting units emitting second color light and a second compensation layer located between the first electrode and the second light-emitting units or/and between the second electrode and the second light-emitting units;

A color of the light emitted by the first light-emitting units is different from a color of the light emitted by the second light-emitting units, and a thickness of the first compensation layers is different from a thickness of the second compensation layer.

In the display panel of the present disclosure, the first light-emitting units are red light-emitting units, and the second light-emitting units are a green light-emitting units;

A thickness of the second compensation layer is greater than a thickness of the first compensation layers.

In the display panel of the present disclosure, the light-emitting device layer further includes a plurality of third light-emitting units emitting third color light and a third compensation layer located between the first electrode and the third light-emitting units or/and between the second electrode and the third light-emitting units;

The third light-emitting units are blue light-emitting units, and the thickness of the first compensation layers is greater than a thickness of the third compensation layer.

A mobile terminal including a terminal body and a display panel is further disclosed in the present disclosure, wherein the terminal body and the display panel are combined into one;
the display panel includes a first electrode, a light-emitting device layer, and a second electrode stacked in order;
the light-emitting device layer includes a plurality of first light-emitting units emitting first color light, a plurality of first compensation layers disposed corresponding to the first light-emitting units, and a hole transport layer and an electron transport layer located on two sides of the first light-emitting units;
the first compensation layers are located between the first electrode and the first light-emitting units, and a hole transport rate of the first compensation layers is greater than a hole transport rate of the hole transport layer; and/or,
the first compensation layers are located between the second electrode and the first light-emitting units, and an electron transport rate of the first compensation layers is greater than an electron transport rate of the electron transport layer.

In the mobile terminal of the present disclosure, he first compensation layers are located between the first electrode and the first light-emitting units;

The first compensation layers include a hole-type dopant having an electron withdrawing group.

In the mobile terminal of the present disclosure, a concentration of the hole-type dopant ranges from 1% to 6%, and the hole-type dopant includes at least one of HAT-CN, F4-TCNQ, SbCI5 or FeCI3.

In the mobile terminal of the present disclosure, the display panel includes a pixel definition layer, the pixel definition layer includes a plurality of pixel openings, and the first light-emitting units are located in the pixel opening;

The first electrode includes a first portion corresponding to the pixel opening, and a projection of the first portion projected on the secondelectrode is located in a projection of the first compensation layers projected on the second electrode.

In the mobile terminal of the present disclosure, the first compensation layers are located between the second electrode and the first light-emitting units;

The first compensation layers include an electron-type dopant having an electron donating group.

In the mobile terminal of the present disclosure, a concentration of the electron-type dopant ranges from 1 % to 6%, and the electron-type dopant includes an alkali metal or an alkali metal salt.

In the mobile terminal of the present disclosure, a projection of the first light-emitting units projected on the second electrode is located in a projection of the first compensation layers projected on the second electrode.

In the mobile terminal of the present disclosure, the light-emitting device layer further includes a plurality of second light-emitting units emitting second color light and a second compensation layer located between the first electrode and the second light-emitting units or/and between the second electrode and the second light-emitting units;

A color of the light emitted by the first light-emitting units is different from a color of the light emitted by the second light-emitting units, and a thickness of the first compensation layers is different from a thickness of the second compensation layer.

In the mobile terminal of the present disclosure, the first light-emitting units are red light-emitting units, and the second light-emitting units are a green light-emitting units;

A thickness of the second compensation layer is greater than a thickness of the first compensation layers.

In the mobile terminal of the present disclosure, the light-emitting device layer further includes a plurality of third light-emitting units emitting third color light and a third compensation layer located between the first electrode and the third light-emitting units or/and between the second electrode and the third light-emitting units;

The third light-emitting units are blue light-emitting units, and the thickness of the first compensation layers is greater than a thickness of the third compensation layer.

### Beneficial Effects

A display panel and a mobile terminal are disclosed in the present disclosure. A light-emitting device layer of the display panel includes a plurality of first light-emitting units, a plurality of first compensation layers disposed corresponding to the first light-emitting units. The first compensation layers are located on at least one side of the first light-emitting units. A hole transport rate of the first compensation layers is greater than a hole transport rate of a hole transport layer, and/or an electron transport rate of the first compensation layers is greater than an electron transport rate of an electron transport layer. By disposing compensation layers on at least one side of the light-emitting units in the present disclosure, the transfer rate of electrons or/and holes in the light-emitting unit are enhanced, such that starting voltages of the light-emitting units are compensated to solve the technical problem of color shift occurring in the display panel at low gray level.

### DESCRIPTION OF DRAWINGS

FIG. 1 is a first cross-sectional view of a display panel in the present disclosure.

FIG. 2 is a structural schematic view of a light-emitting unit of the display panel in the present disclosure; and

FIG. 3 is a second cross-sectional view of a display panel in the present disclosure.

FIG. 4 is a third cross-sectional view of a display panel in the present disclosure.

FIG. 5 is a first structural schematic view of a display panel in the present disclosure.

FIG. 6 is a second structural schematic view of a display panel in the present disclosure.

FIG. 7 is a comparison diagram of the experimental results between a display panel of the present disclosure and the current display panel.

FIG. 8 is a flow chart of a method of manufacturing a display panel in the present disclosure.

FIGS. 9a to FIGS. 9h are process diagrams of a method of manufacturing a display panel in the present disclosure.

FIG. 10 a schematic diagram of a chemical structure of HAT-CN in the present disclosure.

FIG. 11 is a schematic diagram of a chemical structure of F4-TCNQ in the present disclosure.

### DETAILED DESCRIPTION OF PREFERRED EMBODIMENTS

The technical solutions in the embodiments of the present disclosure are clearly and completely described below in conjunction with the accompanying drawings in the embodiments of the present disclosure. Obviously, the described embodiments are only a part of the embodiments of the present disclosure rather than all of the embodiments. Based on the embodiments in the present disclosure, all other embodiments obtained by a person of ordinary skill in the art without creative efforts fall within the claim scope of the present disclosure.

In the current structure of OLED displays, when a voltage is supplied to one sub-pixel, holes generated by an anode or electrons generated by a cathode are transferred to an adjacent sub-pixel through the corresponding common layer, such that a starting voltage of the sub pixel is inaccurate, resulting in the technical problem of color shift occurring in OLED display device at low gray level. The following technical solutions are provided in the present disclosure to solve the above technical problem.

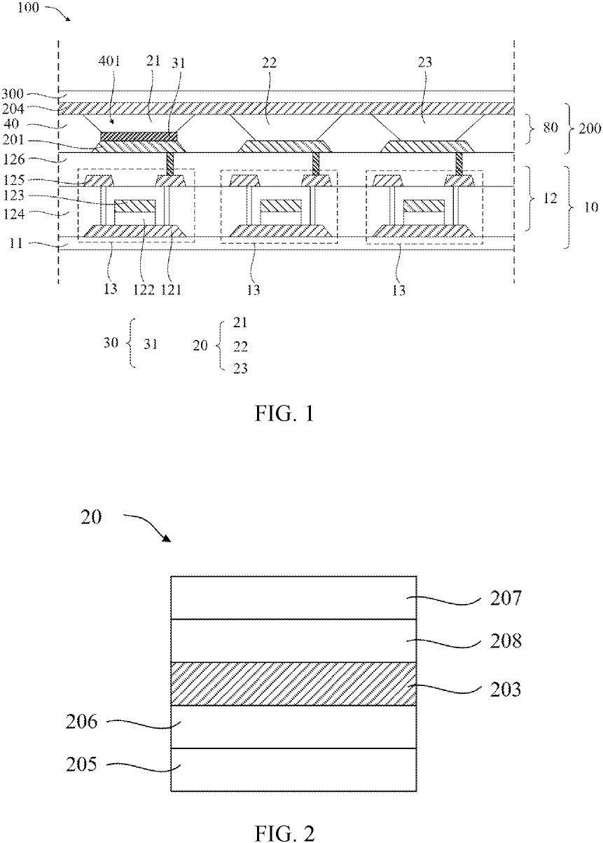

References are made to FIGS. 1 to FIG.6. The present disclosure provides a display panel 100 including a first electrode, a light-emitting device layer 80, and a second electrode which are stacked in order.

In the present embodiment, the light-emitting device layer 80 may include a plurality of first light-emitting units 21 emitting first color light, a plurality of first compensation layers 31 disposed corresponding to the first light-emitting units 21, and a hole transport layer and an electron transport layer located on two sides of the first light-emitting units.

In the present embodiment, the first compensation layers 31 are located between the first electrode and the first light-emitting units 21. A hole transport rate of the first compensation layers 31 is greater than a hole transport rate of the hole transport layer 206. Alternatively, the first compensation layers 31 are located between the second electrode and the first light-emitting units 21, and an electron transport rate of the first compensation layers 31 is greater than an electron transport rate of the electron transport layer 207.

A display panel 100 is disclosed in the present disclosure. The light-emitting device layer 80 of the display panel 100 includes a plurality of first light-emitting units 21 and a plurality of first compensation layers 31 disposed corresponding to the first light-emitting units 21. The first compensation layers 31 are located on at least one side of the first light-emitting units 21. A hole transport rate of the first compensation layers 31 is greater than a hole transport rate of a hole transport layer 206, and/or an electron transport rate of the first compensation layers 31 is greater than an electron transport rate of an electron transport layer 207. By disposing compensation layers on at least one side of the light-emitting units in the present disclosure, the transfer rate of electrons or/and holes in the light-emitting units are enhanced, such that the starting voltages of the light-emitting units are compensated to solve the technical problem of color shift occurring in the display panel 100 at low gray level.

It should be noted that electrodes on two sides of the light-emitting device layer 80 are an anode and a cathode generally, and thus the first electrode is described as the anode layer 201 and the second electrode is described as the cathode layer 204 in the following descriptions.

The technical solution of the present disclosure is described in conjunction with specific embodiments.

Reference is made to FIG. 1. FIG. 1 shows a first cross-sectional view of the display panel 100 in the present disclosure.

In the present embodiment, the display panel 100 may include an array substrate 10, a light-emitting function layer 200 disposed on the array substrate 10, and an encapsulation layer 300 located on the light-emitting function layer 200. The light-emitting function layer 200 includes an anode layer, a light-emitting device layer 80 located on the anode layer 201, and a cathode layer 204 located on the light-emitting device layer 80. The light-emitting device layer 80 includes a plurality of light-emitting units 20.

In the present embodiment, the array substrate 10 may include a substrate 11 and a driving circuit layer 12 disposed on the substrate 11. The substrate 11 may be a flexible substrate or a rigid substrate. When the substrate 11 is the rigid substrate, the substrate 11 may be made of glass, quartz, etc. When the substrate 11 is the flexible substrate, the substrate 11 may be made of a material such as polyimide.

In the present embodiment, the driving circuit layer 12 may include a plurality of thin film transistors 13. The thin film transistors 13 may be etch-stopper type, back channel etch type, or top-gate thin film transistor, and the present disclosure is not limited thereto. For example, the top gate thin film transistor may include an active layer 121 disposed on the substrate 11, a gate insulation layer 122 disposed on the active layer 121, a gate layer 123 disposed on the gate insulation layer 122, an inter-insulation layer 124 disposed on the gate layer 123, a source/drain layer 125 disposed on the inter-insulation layer 124, and a planarization layer 126 disposed on the source/drain layer 125. The aforementioned top-gate thin film transistor is not limited to a single gate structure, but may also be provided with a dual gate structure.

In the display panel 100 of the present disclosure, the display panel 100 further includes a pixel definition layer 40 disposed on the same layer as the light-emitting function layer 200, and the pixel definition layer 40 includes a plurality of pixel openings 401. The light-emitting function layer 200 may include an anode layer 201 disposed on the planarization layer 126, a plurality of light-emitting units 20 disposed on the anode layer 201, and a cathode layer 204 disposed on the light-emitting units 20. The light-emitting units 20 are located in the pixel openings 401, and one of the light-emitting units 20 is corresponding to one of the pixel openings 401. The anode layer 201 is configured to provide holes for withdrawing electrons, and the cathode layer 204 is configured to provide electrons required by the light-emitting units 20.

References are made to FIG. 1 and FIG. 2. Each of the light-emitting units 20 may include a hole transport layer 206 disposed on the anode layer 201, a light-emitting layer 203 disposed on the hole transport layer 206, an electron transport layer 207 disposed on the light-emitting layer 203, and a cathode layer 204 disposed on the electron transport layer 207. The light-emitting function layer 200 shown in FIG. 1 may include a first light-emitting unit 21, a second light-emitting unit 22, and a third light-emitting unit 23. The colors of lights emitted by the first light-emitting unit 21, the second light-emitting unit 22, and the third light-emitting unit 23 are different. For example, the first light-emitting unit 21 may be a red light-emitting unit, the second light-emitting unit 22 may be a green light-emitting unit, and the third light-emitting unit 23 may be a blue light-emitting unit.

In the structure shown in FIG. 1, since the hole transport layers 206 and the electron transport layers 207 of the adjacent light-emitting units 20 are shared, the holes generated by the anode layer 201 may be transferred to the adjacent light-emitting units 20 through the hole transport layer 206, or the electrons generated by the cathode layer 204 may be transferred to the adjacent light-emitting units 20 through the electron transport layer 207. For example, on the condition of the display panel 100 at low gray level, when the second light-emitting unit 22 starts to emit light, the holes generated by the anode layer 201 or the electrons generated by the cathode layer 204 may be transferred to the first light-emitting unit 21 or the third light-emitting unit 23 through the corresponding transport layer, resulting in the leakage current of the second light-emitting unit 22. That is, the second light-emitting unit 22 cannot display the predetermined brightness. Moreover, when the first light-emitting unit 21 and the third light-emitting unit 23 are in a non-illuminated state, introducing the holes or electrons from the second light-emitting unit 22 may cause the first light-emitting unit 21 and the third light-emitting unit 23 to emit faint light, resulting in the technical problem of color shift occurring in the display panel 100 at low gray level.

In the present embodiment, in a light-emitting direction of the light-emitting units 20, the light-emitting function layer 200 further includes a first compensation layer 31 disposed on at least one side of at least one of the light-emitting unit 20. The first compensation layer 31 is configured to compensate the starting voltages of the light-emitting unit 20.

Reference is made to FIG. 1. In the present embodiment, the first compensation layer 31 may include a first compensation layer 31 located between the anode layer 201 and the first light-emitting unit 21. The first compensation layer 31 may be made by doping at least one organic/inorganic material in the process such as blending or doping. The first compensation layer 31 may include a hole-type dopant, such as HAT-CN (see FIG. 10), F4-TCNQ (see FIG. 11), SbCI5 (antimony pentachloride), or FeCI3 (iron trichloride).

In the present embodiment, since the hole-type dopant has more free holes, the hole-type dopant has a strong electron withdrawing group. When the anode layer 201 and the cathode layer 204 are applied with corresponding voltages, an electron withdrawing group in the hole-type dopant can withdraw an electron from the first compensation layer 31 and retain a hole. The retained hole is transferred to the first light-emitting unit 21 through the hole transport layer 206 under the voltage effects of the anode layer 201 and the cathode layer 204, and is combined with the electron transferred from the cathode layer 204 to produce the light source. Therefore, the first compensation layer 31 is equivalent to compensating the starting voltage of the first light emitting unit 21.

In the present embodiment, the thickness of the first compensation layer 31 and the amount of dopants in the first compensation layer 31 are positively correlated with the corresponding compensation voltage. For example, the greater the thickness of the first compensation layer 31 is (the greater amount of the dopants therein is under the same proportion), the larger the voltage compensated for the first light-emitting unit 21 by the first compensation layer 31 is. Therefore, in the present embodiment, the thickness of the electrical compensation may be adjusted adaptively according to the leakage currents of different sub-pixels.

In the present embodiment, the film thickness of the first compensation layer 31 may range from 5 nm to 80 nm. For the current manufacturing process of the display panel 100, when the film thickness of the first compensation layer 31 is less than 5 nm, the film thickness is too thin, the evaporation process is more difficult, and the formed film layer may appear noncontinuous. When the film thickness of the first compensation layer 31 is greater than 80 nm, the thickness of the film layer is too large, which may lead to the failure of microcavity effect of the light-emitting unit 20 and affect the luminous efficiency of the light-emitting unit 20.

In the present embodiment, the film thickness of the first compensation layer 31 may range from 15 nm to 30 nm.

In the present embodiment, the concentration of the dopant in the first compensation layer 31 may range from 0.5% to 20%. For the current manufacturing process of the display panel 100, when the concentration of the dopant in the first compensation layer 31 is less than 0.5%, over-low concentration of the dopant may lead to non-uniform distribution of the dopant in the film layer, lowering the stability of the process. When the concentration of the dopant in the first compensation layer 31 is greater than 20%, the luminous efficiency and luminous life of the first light-emitting unit 21 may be affected due to over-high doping concentration of the dopants.

In the present embodiment, the concentration of the dopants in the first compensation layer 31 may range from 1% to 6%.

In the present embodiment, by disposing the first compensation layers 31 between the anode layer 201 and the first light-emitting units 21 in the present disclosure, the dopants in the first compensation layers 31 generate the holes by withdrawing the electrons and provide the holes to the first light-emitting units 21 through the corresponding hole transport layer 206, which enhances the rate of transferring hole to the light-emitting unit, such that the starting voltages of the first light-emitting units 21 are compensated, thereby ensuring that the starting voltages of the first light-emitting units 21 are normal. Moreover, the thicknesses of the first compensation layers 31 and the concentrations of the hole-type dopants in the first compensation layers 31 are adjusted adaptively according to the condition of the leakage currents of the first light-emitting units 21, so that the first light-emitting units 21 display the predetermined brightness at low gray level, thereby solving the technical problem of color shift occurring in the display panel 100 at low gray level and improving the accuracy of the luminescent color of the display panel 100.

Reference is made to FIG. 1. The anode layer 201 includes a first portion corresponding to the pixel opening 401, and a projection of the first projected on the cathode layer 204 is located in a projection of the first compensation layer 31 projected on the cathode layer 204. The first portion of the anode layer 201 is the portion of the anode layer 201 that is not covered by the pixel definition layer 40, i.e., the portion of the anode layer 201 exposed in the pixel opening 401.

In the present embodiment, the holes generated by the anode layer 201 are transferred to the adjacent light-emitting unit 20 through the hole transport layer 206. Therefore, if the first compensation layer 31 does not completely cover the first portion of the anode layer 201, the holes generated by the first portion of the anode layer 201 may be transferred to the adjacent light-emitting units 20 through the hole transport layer 206 which is in direct contact with the first portion of the anode layer 201.

In the present embodiment, the first compensation layer 31 completely covers the first portion of the anode layer 201 to prevent the holes generated by the first portion of the anode layer 201 from being directly transferred to the adjacent light-emitting units 20 through the hole transport layer 206. The holes passing through the first compensation layer 31 may be transferred to the light-emitting unit 20 under the action of the electric field formed by the anode layer 201 and the cathode layer 204. At the same time, the holes generated by the first compensation layer 31 compensate the starting voltage of the light-emitting unit 20, such that the light-emitting unit 20 display the predetermined brightness at low gray level, thereby solving the technical problem of color shift occurring in the display panel 100 at low gray level and improving the accuracy of the luminescent color of the display panel 100.

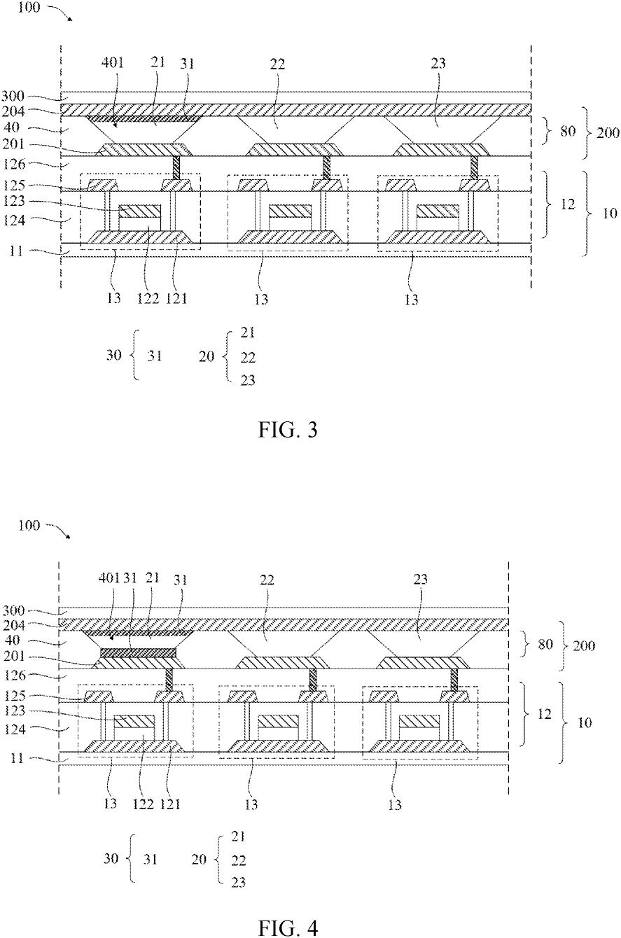

Reference is made to FIG. 3. FIG. 3 is a second cross-sectional view of the display panel 100 in the present disclosure. The first compensation layer 31 may be located between the cathode layer 204 and the first light-emitting unit 21. The first compensation layer 31 may be made by doping at least one organic/inorganic material in the process such as blending or doping. The first compensation layer 31 may include an electron-type dopant, such as an alkali metal or an alkali metal salt (e.g., Li, Cs and salts thereof).

In the present embodiment, since the electron-type dopant has more free electrons, the electron-type dopant has a strong hole withdrawing group, which may also be referred to as an electron donating group. When the anode layer 201 and the cathode layer 204 are applied with corresponding voltages, a hole withdrawing group in the electron-type dopant can withdraw a hole from the first compensation layer 31 and retain an electron. The retained electron is transferred to the first light-emitting unit 21 through the electron transport layer 207 under the voltage effects of the anode layer 201 and the anode layer 204, and is combined with the hole transferred from the anode layer 201 to produce the light source. Therefore, the first compensation layer 31 is equivalent to compensating the starting voltage of the first light emitting unit 21.

In the present embodiment, the thickness of the first compensation layer 31 and the concentration of electron-type dopant in the first compensation layer 31 may be referred to the embodiment in FIG. 1, and the description is not further provided herein.

In the present embodiment, by disposing the first compensation layers 31 between the cathode layer 204 and the first light-emitting units 21 in the present disclosure, the dopants in the first compensation layers 31 generate the electrons by withdrawing the holes and provide the electrons to the first light-emitting units 21 through the corresponding electron transport layer 207, which enhances the rate of transferring electron to the light-emitting unit, such that the starting voltages of the first light-emitting units 21 are compensated, thereby ensuring that the starting voltages of the first light-emitting units 21 are normal. Moreover, the thicknesses of the first compensation layers 31 and the concentrations of the hole-type dopants in the first compensation layers 31 are adjusted adaptively according to the condition of the leakage currents of the first light-emitting units 21, so that the first light-emitting units 21 display the predetermined brightness at low gray level, thereby solving the technical problem of color shift occurring in the display panel 100 at low gray level and improving the accuracy of the luminescent color of the display panel 100.

In the present embodiment, a projection of the first light-emitting unit 21 projected on the cathode layer 204 may be located in a projection of the first compensation layer 31 projected on the cathode layer 204. Similar to anode layer 201, since the electrons generated by the cathode layer 204 are transferred to the adjacent light-emitting units 20 through the electron transport layer 207. Accordingly, if the first compensation layer 31 does not isolate the area between the cathode layer 204 and light-emitting units, the electrons generated by the cathode layer 204 may be transferred to the adjacent light-emitting units through the electron transport layer 207 which is in direct contact with the light-emitting units 20.

Reference is made to FIG. 4. FIG. 4 is a third cross-sectional view of the display panel 100 of the present disclosure is shown in FIG. 4. The first compensation layers 31 may be located between the cathode layer 204 and the first light-emitting unit 21, and between the anode layer 201 and the first light-emitting unit 21. The structure shown in FIG. 4 is equivalent to the combination of the embodiments shown in FIG. 1 and FIG. 3. The first compensation layer 31 located between the anode layer 201 and the first light-emitting unit 21 may include the hole-type dopant, and the first compensation layer 31 located between the cathode layer 204 and the first light-emitting unit 21 may include the electron-type dopant, both of which may be referred to the embodiments in FIG. 1 and FIG. 3 for thickness and concentration parameters.

For the display panel 100 at low gray scale, among the red, green, and blue sub-pixels, the green sub-pixel has more serious light leakage, followed by the red sub-pixel with light leakage, and the blue sub-pixel has weaker light leakage. Therefore, the color shift varies for different colors of sub-pixels.

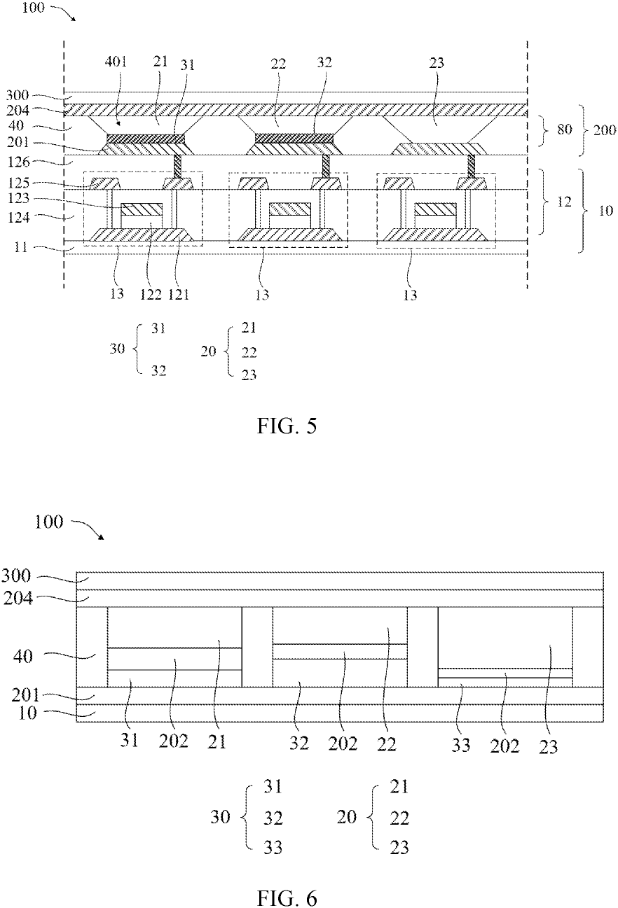

Reference is made to FIG. 5. FIG. 5 is a first structural schematic view of the display panel 100 in the present disclosure. The electrical compensation layer 30 may include a first compensation layer 31 corresponding to the first light-emitting unit 21 and a second compensation layer 32 corresponding to the second light-emitting unit 22, and the arrangement position of the second compensation layer 32 may be referred to the position of the first compensation layer 31.

In the present embodiment, the film thicknesses of the first compensation layer 31 and the second compensation layer 32 may be different.

According to the aforementioned limitations, the first light-emitting unit 21 may be a red light-emitting unit, and the second light-emitting unit 22 may be a green light-emitting unit. Since the green sub-pixel has the most serious light leakage, followed by the red sub-pixel with light leakage, and the blue sub-pixel has the weakest light leakage, the film thickness of the second compensation layer 32 is greater than the film thickness of the first compensation layer 31 in the present disclosure. That is, the green sub-pixel has more serious light leakage, and thus the thickness film layer of the second compensation layer 32 is the largest. The blue sub-pixel has the weakest light leakage, and thus no compensation layer is arranged. The film thickness of the first compensation layer 31 may be smaller than the film thickness of the second compensation layer 32.

Moreover, in the present embodiment, the concentrations of the dopants in the first compensation layer 31 and the second compensation layer 32 can be adjusted adaptively according to the different colors of sub-pixels. That is, the thickness of the electrical compensation layer 30 and the concentration of the dopants are adjusted at the same time to satisfy the starting voltage required by the corresponding light-emitting unit 20 and the thickness of the cavity length required for the microcavity effect.

Reference is made to FIG. 6. FIG. 6 is a second structural schematic view of the display panel 100 in the present disclosure. The electrical compensation layer 30 may include a first compensation layer 31 corresponding to the first light-emitting unit 21, a second compensation layer 32 corresponding to the second light-emitting unit 22, and a third compensation layer 33 corresponding to the third light-emitting unit 23. The film thicknesses of the first compensation layer 31, the second compensation layer 32, and the third compensation layer 33 are different from each other.

According to the aforementioned limitations, the first light-emitting unit 21 may be a red light-emitting unit, the second light-emitting unit 22 may be a green light-emitting unit, and the third light-emitting unit 23 may be a blue light-emitting unit. Since the green sub-pixel has the most serious light leakage, followed by the red sub-pixel with light leakage, and the blue sub-pixel has the weakest light leakage, the film thickness of the second compensation layer 32 is greater than the film thickness of the first compensation layer 31 and the film thickness of the first compensation layer 31 is greater than the film thickness of the third compensation layer 33 in the present disclosure. That is, the green sub-pixel has more serious light leakage, and thus the thickness film layer of the second compensation layer 32 is the largest. The blue sub-pixel has the weakest light leakage, and thus the thickness film layer of the third compensation layer 33 is the smallest.

Moreover, in the present embodiment, the concentrations of the dopants in the first compensation layer 31, the second compensation layer 32, and the third compensation layer 33 can be adjusted adaptively according to the different colors of sub-pixels. That is, the thickness of the electrical compensation layer 30 and the concentration of the dopants are adjusted at the same time to satisfy the starting voltage required by the light-emitting unit 20 and the thickness of the cavity length required for the microcavity effect.

Due to the inherent characteristics of light-emitting materials, the red light-emitting unit, the green light-emitting unit, and the blue light-emitting unit have different luminous efficiency and luminous life. Since the green light-emitting unit has the longest luminous life and greatest luminous efficiency and the blue light-emitting unit has the shortest luminous life, the thickness of the blue light-emitting unit may be greater than the thickness of the red light-emitting unit and the thickness of the red light-emitting unit may be greater than the thickness of the green light-emitting unit when planning the film thickness.

Reference is made to FIG. 6. For the display panel 100 in the present disclosure, in order to ensure the flatness of the film layer structure, the light-emitting units 20 include a cavity length adjustment layer 202 disposed between the anode layer 201 and the electrical compensation layer 30, and the thicknesses of the cavity length adjustment layers 202 are not the same for different luminescent colors.

In the present embodiment, the cavity length adjustment layer 202 is configured for not only adjusting the flatness of the film layer, but also adjusting the luminous efficiency of the light-emitting unit 20. For example, when the display panel 100 is top emission type, the anode layer 201 may be composed of fully reflective material, and the cathode layer 204 may be composed of semi-reflective material. In order to avoid light interference inside the microcavity, a ratio of the thickness of the microcavity formed by the anode layer 201 and the cathode layer 204 to a wavelength of the color of corresponding emitting light is required to be 0.5 m:1, wherein m is a positive integer. Similarly, when the display panel 100 is bottom emission type, the detailed working principle thereof is equal to that of the top emission type, and thus the description is not further provided herein.

For the top emission type display panel 100, the current anode layer 201 is generally composed of three layers of metal such as a laminated structure of indium tin oxide, silver metal, and indium tin oxide. The metal silver is a total reflection material, and the light emitted from the light-emitting layer 203 may be reflected to the cathode layer 204 by the metal silver. Therefore, the distance from the light-emitting center of the light-emitting layer 203 to the surface of the metal silver is required to satisfy a certain spacing in order to ensure the luminous efficiency of the light-emitting unit 20.

In the present embodiment, the spacing between the center of the light-emitting layer 203 and the predetermined position of the anode layer 201 is 0.5 nλ, wherein A is the wavelength of the luminescent color corresponding to the light-emitting layer 203, and n is a positive integer. That is, the spacing between the center of the light-emitting layer 203 and the surface of the metal silver of the anode layer 201 is 0.5 nλ.

In the present embodiment, since the cavity length adjustment layer 202 is disposed between the anode layer 201 and the electrical compensation layer 30, the thicknesses of the cavity length adjustment layers 202 required for different luminescent colors are different according to the spacing limitation between the center of the light-emitting layer 203 and the metal silver. For example, since the wavelength of the red light is the largest and the wavelength of the blue light is the smallest, the thickness of the cavity length adjustment layer 202 corresponding to the red light is the largest and the thickness of the cavity length adjustment layer 202 corresponding to the blue light is the smallest.

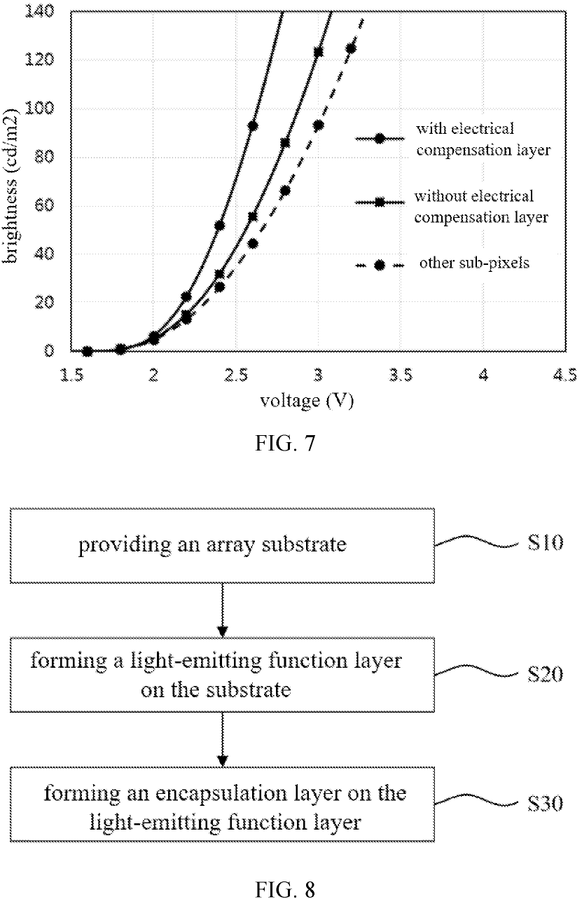

Reference is made to FIG. 7. FIG. 7 shows a comparison of the experimental results between the display panel in the present disclosure and the current display panel. FIG. 7 shows a curve of the case without the electrical compensation layer, a curve of the case with the electrical compensation layer, and a curve of the case of other sub-pixels. The solid lines shown in FIG. 7 are the curves of the comparison result for the green sub-pixel. The dashed line is the curve for the red sub-pixel or the blue sub-pixel. It can be seen in the curves that for different solutions to achieve the same brightness, e.g., the brightness value of 20 cd/m2 at a low gray scale, the voltage required in the current display panel without the electrical compensation layer is 2.27 V, and the voltage required in the display panel provided with the compensation layer in the present disclosure is 2.18 V. In comparison with the current technical solution, the voltage required for achieving the same brightness is reduced, such that the voltage of the light-emitting unit is compensated by the electrical compensation layer. Moreover, with respect to the red sub-pixel or blue sub-pixel, the voltage required for achieving the same brightness is smaller for the green sub-pixel since the green sub-pixel has a higher luminous efficiency.

In low grayscale state, the green sub-pixel is taken as an example, and the specific results are as follows.

In the case without the electrical compensation layer, the starting voltage is 2.26 V and the color shift value ranges from 0.005 to 0.007.

In the case with the electrical compensation layer, the starting voltage is 2.09 V and the color shift value ranges from 0.003 to 0.004.

The formula for calculating the color shift value in this experiment is:
ΔCIE = CIE*(low gray scale) - CIE*(L255);
wherein CIE*(low gray scale) is the CIE value of the green sub-pixel at low gray level and CIE*(L255) is the CIE value of the green sub-pixel at high gray level. According to the data in the above table, the starting voltage of the green sub-pixel is reduced from 2.26 V to 2.09 V, and the color shift value at low gray scale is reduced by 0.002-0.003. Therefore, there is a great improvement for the display panel with the electrical compensation layer.

In the present embodiment, the materials of the cavity length adjustment layer 202, the hole injection layer 205, the light-emitting layer 203, the hole transport layer 206, the electron transport layer 207, and the electron injection layer 208 may be, but not limited to, small organic molecule materials. The cavity length adjustment layer 202, the hole injection layer 205, the hole transport layer 206, the light-emitting layer 203, the electron transport layer 207, and the electron injection layer 208 may be formed by a vapor deposition process.

In the present embodiment, the cavity length adjustment layer 202 may be at least one of the hole-type small organic molecules 2TNATA, NPB, and TAPC, and is formed on the anode layer 201 or electrical compensation layer 30 by using a metal fine mask in vacuum vapor deposition. The film thickness of the cavity length adjustment layer 202 may range from 20 nm to 180 nm.

In the present embodiment, the electron transport layer 207 and the electron injection layer 208 may be at least one of TPBi, BPhen, TmPyPB. The thickness of the electron transport layer 207 and the electron injection layer 208 may range from 20 nm to 80 nm.

In the present embodiment, the thickness of the light-emitting layer 203 may range from 20 nm to 50 nm.

In the present embodiment, the material of the cathode layer 204 may be at least one of Yb, Ca, Mg, Ag. For example, an AgMg alloy formed with Ag and Mg in a ratio of 10:1, and the thickness of the cathode layer 204 may range from 8 nm to 20 nm.

In the aforementioned embodiments, the encapsulation layer may be a thin film encapsulation layer, which may include a first inorganic layer, a first organic layer disposed on the first inorganic layer, and a second inorganic layer disposed on the first organic layer. The detailed structure is not further provided herein.

A display panel 100 is disclosed in the present disclosure. The light-emitting device layer 80 of the display panel 100 includes a plurality of first light-emitting units 21 and a plurality of first compensation layers 31 disposed corresponding to the first light-emitting units 21. The first compensation layers 31 are located on at least one side of the first light-emitting units 21. A hole transport rate of the first compensation layers 31 is greater than a hole transport rate of a hole transport layer 206, and/or an electron transport rate of the first compensation layers 31 is greater than an electron transport rate of an electron transport layer 207. By disposing compensation layers on at least one side of the light-emitting units in the present disclosure, the transfer rate of electrons or/and holes in the light-emitting units are enhanced, such that the starting voltages of the light-emitting units are compensated to solve the technical problem of color shift occurring in the display panel 100 at low gray level.

Reference is made to FIG. 8. A method of manufacturing a display panel 100 is further disclosed in the present disclosure, which includes the following steps.

S10: an array of substrates 10 is provided.

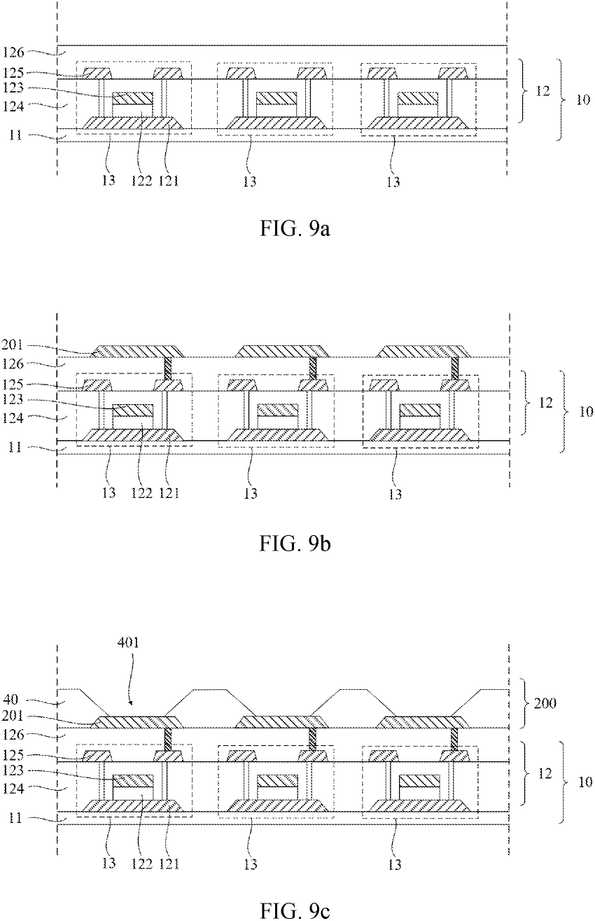

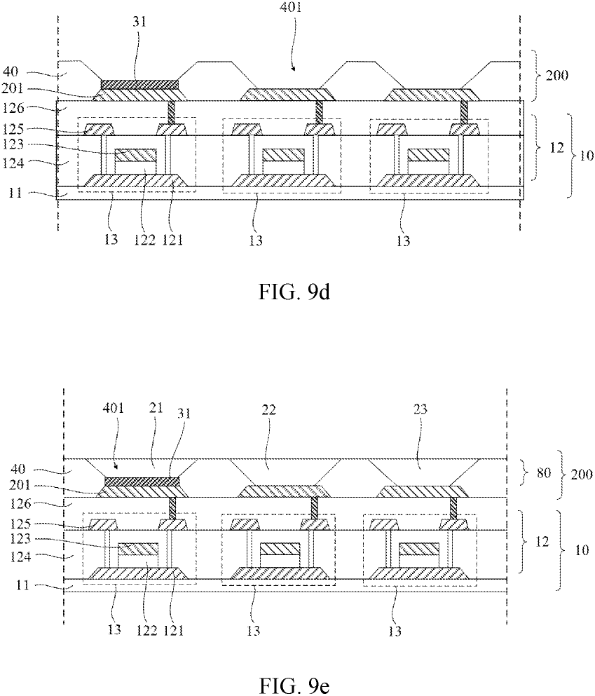

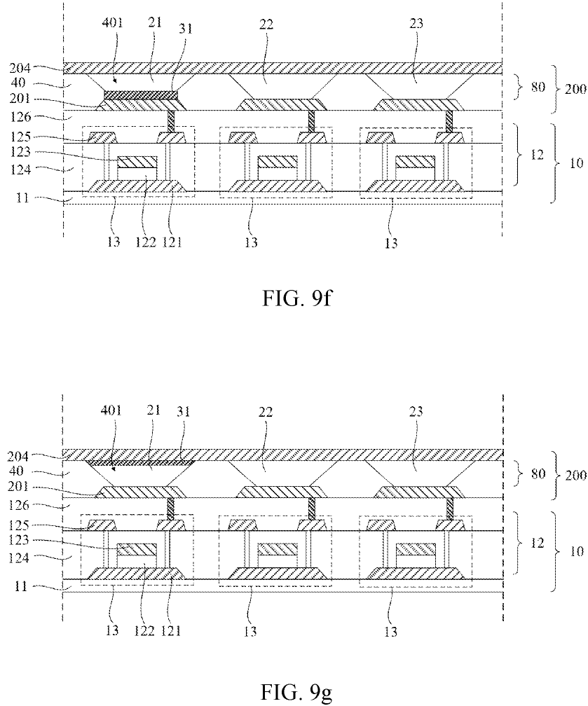

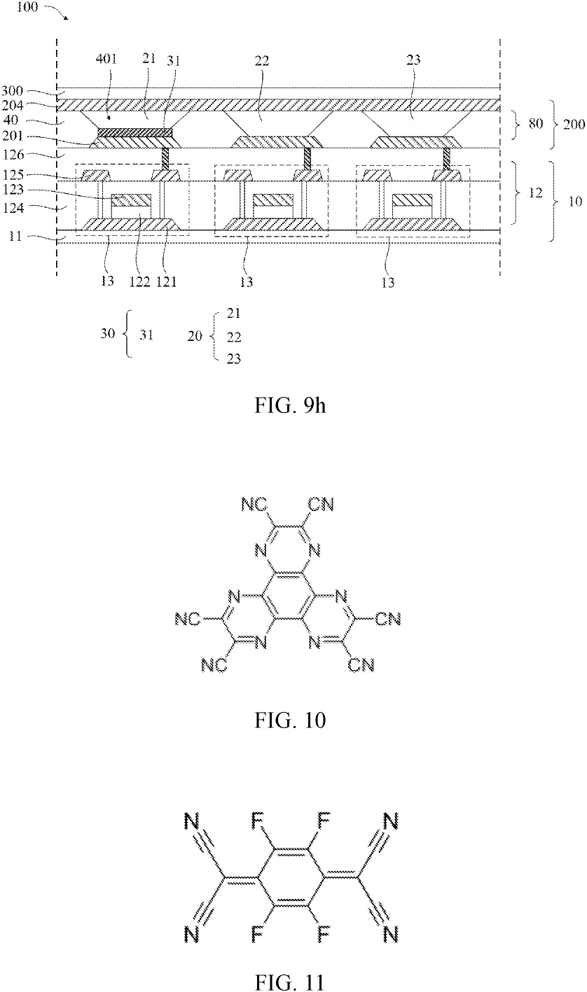

Reference is made to FIG. 9a. The array substrate 10 may include a substrate 11 and a driving circuit layer 12 disposed on the substrate 11. The substrate 11 may be a flexible substrate or a rigid substrate. When the substrate 11 is the rigid substrate, the substrate 11 may be made of glass, quartz, etc. When the substrate 11 is the flexible substrate, the substrate 11 may be a material such as polyimide.

In the present embodiment, the driving circuit layer 12 may include a plurality of thin film transistors 13. The thin film transistors 13 may be etch-stopper type, back channel etch type, or top-gate thin film transistor, and the present disclosure is not limited thereto. For example, the top gate thin film transistor may include an active layer 121 disposed on the substrate 11, a gate insulation layer 122 disposed on the active layer 121, a gate layer 123 disposed on the gate insulation layer 122, an inter-insulation layer 124 disposed on the gate layer 123, a source/drain layer 125 disposed on the inter-insulation layer 124, and a planarization layer 126 disposed on the source/drain layer 125. The aforementioned top-gate thin film transistor is not limited to a single gate structure, but may also be provided with a dual gate structure.

S20: a light-emitting function layer 200 is formed on the substrate 11.

In the present embodiment, the step S20 may include the following steps.

S201: an anode layer 201 is formed on the array substrate 10.

Reference is made to FIG. 9b. The anode layer 201 may be composed of three layers of metal, such as a stacked structure of indium tin oxide, metal silver, and indium tin oxide. The anode layer 201 includes a plurality of anodes, and one of the anodes is corresponding to one sub-pixel of the display panel 100.

After the anode layer 201 is formed, it further includes the step: a pixel definition layer 40 is formed on the anode layer 201.

Reference is made to FIG. 9c. The pixel definition layer 40 is patterned to form a plurality of pixel openings 401, and the pixel openings 401 expose a portion of the anodes.

S202: A first compensation material layer is formed on the anode layer 201, and the first compensation material layer is doped with hole-type dopants to form a first compensation layer 31.

Reference is made to FIG. 9d. The first compensation layer 31 is located within the pixel opening 401. Moreover, the first compensation layer 31 may be deposited before forming the pixel definition layer 40, so as to cover the exposed portion of the anode layer 201.

The first compensation layer 31 may be made by doping at least one organic/inorganic material in the process such as blending or doping. The first compensation layer 31 may include a hole-type dopant, such as HAT-CN (see FIG. 10), F4-TCNQ (see FIG. 11), SbCI5 (antimony pentachloride), or FeCI3 (iron trichloride).

In the present embodiment, the film thickness of the first compensation layer 31 may range from 5 nm to 80 nm. For the current manufacturing process of the display panel 100, when the film thickness of the first compensation layer 31 is less than 5 nm, the film thickness is too thin, the evaporation process is more difficult, and the formed film layer may appear noncontinuous. When the film thickness of the first compensation layer 31 is greater than 80 nm, the thickness of the film layer is too large, which may lead to the failure of microcavity effect of the light-emitting unit 20 and affect the luminous efficiency of the light-emitting unit 20.

In the present embodiment, the film thickness of the first compensation layer 31 may range from 15 nm to 30 nm.

In the present embodiment, the concentration of the dopant in the first compensation layer 31 may range from 0.5% to 20%. For the current manufacturing process of the display panel 100, when the concentration of the dopant in the first compensation layer 31 is less than 0.5%, over-low concentration of the dopant may lead to non-uniform distribution of the dopant in the film layer, lowering the stability of the process. When the concentration of the dopant in the first compensation layer 31 is greater than 20%, the luminous efficiency and luminous life of the first light-emitting unit 21 may be affected due to over-high doping concentration of the dopants.

In the present embodiment, the concentration of the dopants in the first compensation layer 31 may range from 1% to 6%.

S203: A plurality of light-emitting units 20 are formed on the first compensation layer 31.

Reference is made to FIG. 9e. In the present embodiment, the light-emitting function layer 200 may include a first light-emitting unit 21, a second light-emitting unit 22, and a third light-emitting unit 23. The first light-emitting unit 21, the second light-emitting unit 22, and the third light-emitting unit 23 have different luminescent colors from each other. For example, the first light-emitting unit 21 may be a red light-emitting unit, the second light-emitting unit 22 may be a green light-emitting unit, and the third light-emitting unit 23 may be a blue light-emitting unit.

S204: A cathode layer 204 is formed on the plurality of the light-emitting units 20.

Reference is made to FIG. 9f. In the present embodiment, the material of the cathode layer 204 may be at least one of Yb, Ca, Mg, Ag. For example, an AgMg alloy formed by Ag and Mg in a ratio of 10:1, and the thickness of the cathode layer 204 may range from 8 nm to 20 nm.

In the present embodiment, the hole-type dopant has a strong electron withdrawing group. When the anode layer 201 and the cathode layer 204 are applied with corresponding voltages, an electron withdrawing group in the hole-type dopant can withdraw an electron from the first compensation layer 31 and retain a hole. The retained hole is transferred to the second light-emitting unit 22 through the hole transport layer 206 under the voltage effects of the anode layer 201 and the cathode layer 204, and is combined with the electron transferred from the cathode layer 204 to produce the light source.

In the present embodiment, the first compensation layer 31 is equivalent to compensating the starting voltage of the first light emitting unit 21.

In the present embodiment, the thickness of the first compensation layer 31 and the amount of dopants in the first compensation layer 31 are positively correlated with the corresponding compensation voltage. For example, the greater the thickness of the first compensation layer 31 is (the greater amount of the dopants therein is under the same proportion), the larger the voltage compensated for the first light-emitting unit 21 by the first compensation layer 31 is. Therefore, in the present embodiment, the thickness of the electrical compensation may be adjusted adaptively according to the leakage currents of different sub-pixels.

Reference is made to FIG. 9g. In the present embodiment, the step S20 may further include the following steps.

S211: An anode layer 201 is formed on the array substrate 10.

S212: A plurality of light-emitting units 20 are formed on the anode layer 201.

S213: A first compensation material layer is formed on the plurality of the light-emitting units 20, and the first compensation material layer is doped with an electron-type dopant to form a first compensation layer 31.

S214: A cathode layer 204 is formed on the first compensation layer 31.

In the present embodiment, the first compensation layer 31 may be made by doping at least one organic/inorganic material in the process such as blending or doping. The first compensation layer 31 may include an electron-type dopant, such as an alkali metal or an alkali metal salt.

In the present embodiment, the electron-type dopant has a strong hole withdrawing group. When the anode layer 201 and the cathode layer 204 are applied with corresponding voltages, a hole withdrawing group in the electron-type dopant can withdraw a hole from the first compensation layer 31 and retain an electron. The retained electron is transferred to the first light-emitting unit 21 through the electron transport layer 207 under the voltage effects of the anode layer 201 and the anode layer 204, and is combined with the hole transferred from the anode layer 201 to produce the light source. Therefore, the first compensation layer 31 is equivalent to compensating the starting voltage of the first light emitting unit 21.

S30: An encapsulation layer 300 is formed on the light-emitting function layer 200.

Reference is made to FIG. 9h. In the present embodiment, the encapsulation layer 300 may be a thin film encapsulation layer, which may include a first inorganic layer, a first organic layer disposed on the first inorganic layer, and a second inorganic layer disposed on the first organic layer. The detailed structure is not further provided herein.

Reference is made to FIG. 6. In the present embodiment, the light-emitting function layer 200 may further include a cavity length adjustment layer 202. The cavity length adjustment layer 202 can be formed on the anode layer 201 by vapor deposition process, and the detailed process and structure are referred to the aforementioned description.

A display module is further disclosed in the present disclosure, wherein the display module includes the aforementioned display panel, a polarizer layer disposed on the display panel, and a cover plate layer disposed on the polarizer layer.

A mobile terminal is further disclosed in the present disclosure. The mobile terminal includes a terminal body and the aforementioned display panel, and the terminal body and the display panel are combined into one.

A display panel 100 is disclosed in the present disclosure. The light-emitting device layer 80 of the display panel 100 includes a plurality of first light-emitting units 21 and a plurality of first compensation layers 31 disposed corresponding to the first light-emitting units 21. The first compensation layers 31 are located on at least one side of the first light-emitting units 21. A hole transport rate of the first compensation layers 31 is greater than a hole transport rate of a hole transport layer 206, and/or an electron transport rate of the first compensation layers 31 is greater than an electron transport rate of an electron transport layer 207. By disposing compensation layers on at least one side of the light-emitting units in the present disclosure, the transfer rate of electrons or/and holes in the light-emitting units are enhanced, such that the starting voltages of the light-emitting units are compensated to solve the technical problem of color shift occurring in the display panel 100 at low gray level.

It can be understood that for one of ordinary skill in the art, equivalent replacements or changes can be made according to the technical solutions and the invention concept of the present disclosure, and all these changes or replacements shall fall within the scope of the following claims of the present disclosure.

What is claimed is:

1. A display panel comprising a first electrode, a light-emitting device layer, and a second electrode stacked in order;
wherein the light-emitting device layer comprises a plurality of first light-emitting units emitting first color light, a plurality of first compensation layers disposed corresponding to the first light-emitting units, and a hole transport layer and an electron transport layer located on two sides of the first light-emitting units;
wherein the first compensation layers are located between the first electrode and the first light-emitting units, and a hole transport rate of the first compensation layers is greater than a hole transport rate of the hole transport layer; and/or,
the first compensation layers are located between the second electrode and the first light-emitting units, and an electron transport rate of the first compensation layers is greater than an electron transport rate of the electron transport layer.

2. The display panel according to claim 1, wherein the first compensation layers are located between the first electrode and the first light-emitting units;
wherein the first compensation layers comprise a hole-type dopant having an electron withdrawing group.

3. The display panel according to claim 2, wherein a concentration of the hole-type dopant ranges from 1% to 6%, and the hole-type dopant includes at least one of HAT-CN, F4-TCNQ, SbCl5 or FeCl3.

4. The display panel according to claim 2, wherein the display panel comprises a pixel definition layer, the pixel definition layer comprises a plurality of pixel openings, and the first light-emitting units are located in the pixel opening;
wherein the first electrode comprises a first portion corresponding to the pixel opening, and a projection of the first portion projected on the second electrode is located in a projection of the first compensation layers projected on the second electrode.

5. The display panel according to claim 1, wherein the first compensation layers are located between the second electrode and the first light-emitting units;
wherein the first compensation layers comprise an electron-type dopant having an electron donating group.

6. The display panel according to claim 5, wherein a concentration of the electron-type dopant ranges from 1% to 6%, and the electron-type dopant includes an alkali metal or an alkali metal salt.

7. The display panel according to claim 5, wherein a projection of the first light-emitting units projected on the second electrode is located in a projection of the first compensation layers projected on the second electrode.

8. The display panel according to claim 2, wherein the light-emitting device layer further comprises a plurality of second light-emitting units emitting second color light and a second compensation layer located between the first electrode and the second light-emitting units or/and between the second electrode and the second light-emitting units;
wherein a color of the light emitted by the first light-emitting units is different from a color of the light emitted by the second light-emitting units, and a thickness of the first compensation layers is different from a thickness of the second compensation layer.

9. The display panel according to claim 8, wherein the first light-emitting units are red light-emitting units, and the second light-emitting units are a green light-emitting units;
wherein a thickness of the second compensation layer is greater than a thickness of the first compensation layers.

10. The display panel according to claim 9, wherein the light-emitting device layer further comprises a plurality of third light-emitting units emitting third color light and a third compensation layer located between the first electrode and the third light-emitting units or/and between the second electrode and the third light-emitting units;
wherein the third light-emitting units are blue light-emitting units, and the thickness of the first compensation layers is greater than a thickness of the third compensation layer.

11. A mobile terminal, comprising a terminal body and a display panel, wherein the terminal body and the display panel are combined into one;
wherein the display panel comprises a first electrode, a light-emitting device layer, and a second electrode stacked in order;
wherein the light-emitting device layer comprises a plurality of first light-emitting units emitting first color light, a plurality of first compensation layers disposed corresponding to the first light-emitting units, and a hole transport layer and an electron transport layer located on two sides of the first light-emitting units;
wherein the first compensation layers are located between the first electrode and the first light-emitting units, and a hole transport rate of the first compensation layers is greater than a hole transport rate of the hole transport layer; and/or,
the first compensation layers are located between the second electrode and the first light-emitting units, and an electron transport rate of the first compensation layers is greater than an electron transport rate of the electron transport layer.

12. The mobile terminal according to claim 11, wherein the first compensation layers are located between the first electrode and the first light-emitting unit;
wherein the first compensation layers comprise a hole-type dopant having an electron withdrawing group.

13. The mobile terminal according to claim 12, wherein a concentration of the hole-type dopant ranges from 1% to 6%, and the hole-type dopant includes at least one of HAT-CN, F4-TCNQ, SbCl5 or FeCl3.

14. The mobile terminal according to claim 12, wherein the display panel comprises a pixel definition layer, the pixel definition layer comprises a plurality of pixel openings, and the first light-emitting units are located in the pixel opening;
wherein the first electrode comprises a first portion corresponding to the pixel opening, and a projection of the first portion projected on the second electrode is located in a projection of the first compensation layer projected on the second electrode.

15. The mobile terminal according to claim 11, wherein the first compensation layers are located between the second electrode and the first light-emitting unit;
wherein the first compensation layers comprise an electron-type dopant having an electron donating group.

16. The mobile terminal according to claim 15, wherein a concentration of the electron-type dopant ranges from 1% to 6%, and the electron-type dopant includes an alkali metal or an alkali metal salt.

17. The mobile terminal according to claim 15, wherein a projection of the first light-emitting units projected on the second electrode is located in a projection of the first compensation layers projected on the second electrode.

18. The mobile terminal according to claim 12, wherein the light-emitting device layer further comprises a plurality of second light-emitting units emitting second color light and a second compensation layer located between the first electrode and the second light-emitting units or/and between the second electrode and the second light-emitting units;
wherein a color of the light emitted by the first light-emitting units is different from a color of the light emitted by the second light-emitting units, and a thickness of the first compensation layers is different from a thickness of the second compensation layer.

19. The mobile terminal according to claim 18, wherein the first light-emitting units are red light-emitting units, and the second light-emitting units are green light-emitting units;
wherein a thickness of the second compensation layer is greater than a thickness of the first compensation layers.

20. The mobile terminal according to claim 19, wherein the light-emitting device layer further comprises a plurality of third light-emitting units emitting third color light and a third compensation layer located between the first electrode and the third light-emitting units or/and between the second electrode and the third light-emitting units;
wherein the third light-emitting units are blue light-emitting units, and the thickness of the first compensation layers is greater than a thickness of the third compensation layer.
